(19) United States
(12) Patent Application Publication
(10) Pub. No.: US 2004/0016940 A1
(43) Pub. Date: Jan. 29, 2004

(54) Semiconductor device

(75) Inventors: Koichiro Nishizawa, Tokyo (JP); Naoto Andoh, Tokyo (JP); Takao Ishida, Tokyo (JP); Kenji Hosogi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/319,585

(22) Filed: Dec. 16, 2002

(30) Foreign Application Priority Data
Jul. 24, 2002 (JP) 2002-214777

(51) Int. Cl. H01L 31/0328; H01L 31/0336; H01L 31/072; H01L 31/109

(52) U.S. Cl. 257/192

(57) ABSTRACT

A semiconductor device includes a semiconductor substrate, a metal layer formed on a surface of the semiconductor substrate, an electrode formed such that the electrode covers the metal layer, edges of the electrode being in ohmic contact with the semiconductor substrate, a via hole formed right under the metal layer, the via hole having a depth reaching the metal layer from a reverse side of the semiconductor substrate, and a ground electrode formed on an inside surface of the via hole and the reverse side of the semiconductor substrate, the ground electrode being connected to the electrode through the metal layer.

### BACKGROUND OF THE INVENTION

1. Field of the Invention

The present invention relates to a semiconductor device, and more particularly to a semiconductor device suitable for use as a high-frequency IC such as a monolithic microwave integrated circuit (MMIC).

2. Background Art

FIG. 4 is a perspective plan view of a conventional semiconductor device, and FIG. 5 is a cross-sectional view of the semiconductor device taken along line B-B of FIG. 4 as viewed from the direction indicated by the arrows. Referring to FIGS. 4 and 5, gate electrodes 12, source ohmic electrodes 13, and drain ohmic electrodes 14 of FETs (Field Effect Transistors) are formed on a semiconductor substrate 11. Furthermore, a via hole 15 penetrating through the semiconductor substrate 11 from its reverse side is formed. A ground electrode 16 is formed on the inside surface of the via hole 15 and the entire reverse side of the semiconductor substrate 11, and is connected to, for example, the source ohmic electrodes 13 by way of a metal layer 17 formed on the top of the via hole 15 and wires 18.

A method of producing the semiconductor device shown in FIGS. 4 and 5 will be described below. First of all, the gate electrodes 12, the source ohmic electrodes 13, the drain ohmic electrodes 14, the metal layer 17, and the wires 18 are formed on the semiconductor substrate 11 of GaAs by using of the lift-off method. Then, a resist film (not shown) is formed on the reverse side of the semiconductor substrate 11 and patterned such that an opening portion can be formed on the back side of the metal layer 17. After that, the reverse side of the semiconductor substrate 11 is etched by using the resist film as a mask to form the via hole 15 which penetrates through the semiconductor substrate 11 to reach the metal layer 17. At that time, the metal layer 17 acts as an etching stopper. Then, the inside of the via hole 15 and the entire reverse side of the semiconductor substrate 11 are plated with Au to form the ground electrode 16.

Thus, the method of producing the conventional semiconductor device requires a metal layer as an etching stopper to form a via hole. However, if the width of the metal layer is set approximately equal to that of the via hole, the actual width of the formed via hole may be larger than that of the metal layer due to occurrence of overetching at the time of the formation of the via hole. In such a case, the via hole might be exposed to the surface of the semiconductor substrate. Therefore, the width of the metal layer must be set larger than that of the via hole.

On the other hand, the pattern of the metal layer is formed by the lift-off method, as described above. In the actual process, since pattern misalignment might occur depending on the positioning accuracy, it is necessary to provide an alignment margin so that the via hole is not exposed even when the misalignment occurs. Furthermore, the pattern of the source ohmic electrodes connected to the metal layer by way of the wires is also formed by the lift-off method. Also in this case, pattern misalignment might occur, necessitating provision of an alignment margin.

The metal layer must have a certain width to prevent defective devices from being produced due to occurrence of overetching of the via hole or misalignment of the metal layer. Furthermore, an alignment margin for the source ohmic electrodes is also needed to prevent production of defective devices due to occurrence of misalignment of the source ohmic electrodes. However, the above pattern design requirements have greatly hindered the miniaturization of devices.

To miniaturize the device, the via hole may be formed at a position right under a source ohmic electrode. However, if a wet etching method is used, since the source ohmic electrode has lower etching liquid resistance, it is difficult to form a via hole which penetrates through the semiconductor substrate to reach the source ohmic electrode. Such a via hole is also difficult to make even when a dry etching method is used since an alloy formed under the source ohmic electrode might react with the etching gas, which leads to abnormal etching.

The present invention has been devised in view of the above problem. It is, therefore, an object of the present invention to provide a semiconductor device miniaturized such that it is suitable for use as a high-frequency IC such as a monolithic microwave integrated circuit (MMIC).

Other objects and advantages of the present invention will become apparent from the following description.

### SUMMARY OF THE INVENTION

According to one aspect of the present invention, a semiconductor device includes a semiconductor substrate, a metal layer, an electrode, a via hole and a ground electrode. The metal layer is formed on a surface of the semiconductor substrate. The electrode is formed such that the electrode covers the metal layer, edges of the electrode being in ohmic contact with the semiconductor substrate. The via hole is formed right under the metal layer, the via hole having a depth reaching the metal layer from a reverse side of the semiconductor substrate. The ground electrode is formed on an inside surface of the via hole and the reverse side of the semiconductor substrate, the ground electrode being connected to the electrode through the metal layer.

Other and further objects, features and advantages of the invention will appear more fully from the following description.

### BRIEF DESCRIPTION OF THE DRAWINGS

FIG. 1 is a perspective plan view of a semiconductor device according to the present invention.

FIG. 2 is a cross-sectional view of a semiconductor device according to the present invention.

FIG. 3(a)˜(e) show a method producing a semiconductor device according to the present invention, respectively.

FIG. 4 is a perspective plan view of a conventional semiconductor device.

FIG. 5 is a cross-sectional view of a conventional semiconductor device.

### DETAILED DESCRIPTION OF THE PREFERRED EMBODIMENTS

A preferred embodiment of the present invention will be described below with reference to the accompanying drawings.

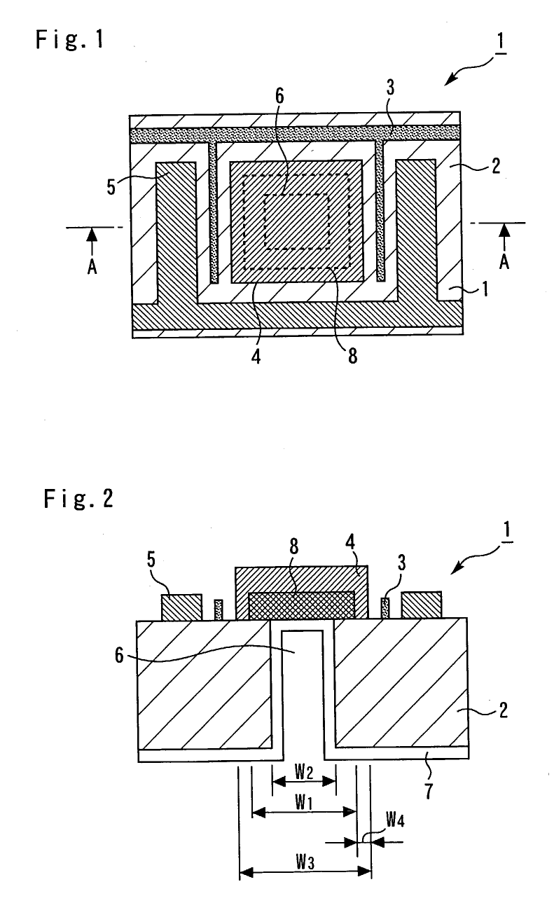

FIG. 1 is a perspective plan view of a semiconductor device according to a preferred embodiment of the present invention, and FIG. 2 is a cross-sectional view of the semiconductor device taken along line A-A of FIG. 1 as viewed from the direction indicated by the arrows. As shown in FIGS. 1 and 2, a semiconductor device 1 of the present invention comprises a semiconductor substrate 2, gate electrodes 3, a source ohmic electrode 4, drain ohmic electrodes 5, a via hole 6, a ground electrode 7, and a metal layer 8. Specifically, the electrodes of each field effect transistor (i.e. a gate electrode 3, a source ohmic electrode 4, and a drain ohmic electrode 5) are formed on the obverse side of the semiconductor substrate 2. The metal layer 8 is also formed on the obverse side of the semiconductor substrate 2. The gate electrodes 3 and the drain ohmic electrodes 5 are directly formed on the obverse side of the semiconductor substrate 2. The source ohmic electrode 4, on the other hand, is formed on the metal layer 8 such that the source ohmic electrode 4 covers the metal layer 8 and its edges are in ohmic contact with the semiconductor substrate 2. It should be noted that a diffusion region (not shown) is formed within the semiconductor substrate 2. As shown in FIG. 1, the metal layer 8 and the source ohmic electrode 4 have a rectangular shape. The via hole 6 is formed right under the metal layer 8 such that it penetrates through the semiconductor substrate 2 to reach the reverse side of the semiconductor substrate 2. Furthermore, the ground electrode 7 is formed on the inside surface of the via hole 6 and the entire reverse side of the semiconductor substrate 2.

The metal layer 8 has a structure in which the metal layer 8 entirely covers the via hole 6, which is formed right under the metal layer 8, so that the via hole 6 is not exposed to the obverse side of the semiconductor substrate 2. Specifically, in FIG. 2, the width W₁ of the metal layer 8 is set equal to the sum of the width W₂ of the via hole 6 and an alignment margin required for the formation of the metal layer 8. For example, the width W₂ of the via hole 6 is preferably set to approximately 15 μm to 30 μm. In this case, the alignment margin for the formation of the metal layer 8 is preferably set to approximately 5 μm to 10 μm. That is, if the width W₂ of the via hole 6 is 15 μm, the width W₁ of the metal layer 8 is preferably set to approximately 20 μm to 25 μm. It should be noted that when the metal layer 8 and the via hole 6 are rectangular as shown in FIG. 1, the above principle is also applied to the direction perpendicular to the direction of the widths W₁ and W₂. That is, for each direction, the width of the metal layer 8 is set equal to the sum of the width of the via hole 6 and the alignment margin for the formation of the metal layer 8.

The source ohmic electrode 4 has a structure in which the source ohmic electrode 4 entirely covers the metal layer 8 so that the metal layer 8 is not exposed. Furthermore, edges of the source ohmic electrode 4 are in direct ohmic contact with the semiconductor substrate 2. In FIG. 2, reference numeral W₄ indicates the length of the portion of the source ohmic electrode 4 which is actually in direct ohmic contact with the semiconductor substrate 2, i.e. contact length. Therefore, the width W₃ of the source ohmic electrode 4 is set equal to the sum of the width W₁ of the metal layer 8, the contact length W₄, and the alignment margin.

In view of the miniaturization of the device, the smaller contact length W₄ is better. However, if the contact length W₄ is too small, a heat generated in the contact portion might undesirably cause the electrode to burn out. Therefore, the contact length W₄ is preferably set to approximately 2 μm to 3 μm. The alignment margin for the formation of the source ohmic electrode 4, on the other hand, is preferably set to approximately 0.5 μm to 1 μm. It should be noted that when the source ohmic electrode 4 is rectangular as shown in FIG. 1, the above principle is also applied to the direction perpendicular to the direction of the width W₃. That is, for each direction, the width W₃ of the source ohmic electrode 4 is set equal to the sum of the width W₁ of the metal layer 8, the contact length W₄, and the alignment margin.

The present invention is characterized in that a source ohmic electrode is formed over a via hole. This structure eliminates the need for providing a certain interval between the via hole and the source ohmic electrode. That is, it is only necessary to consider each alignment margin when determining the dimensions of the source ohmic electrode, making it possible to miniaturize the device.

The present invention is also characterized in that a metal layer is provided between the via hole and the source ohmic electrode. With this arrangement, the metal layer can act as an etching stopper for the formation of the via hole, making it possible to form the via hole without damaging the source ohmic electrode.

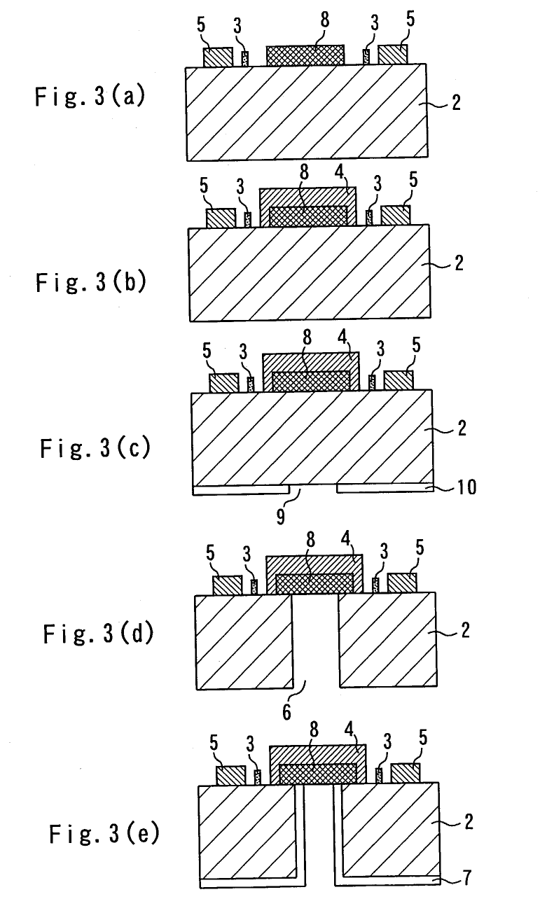

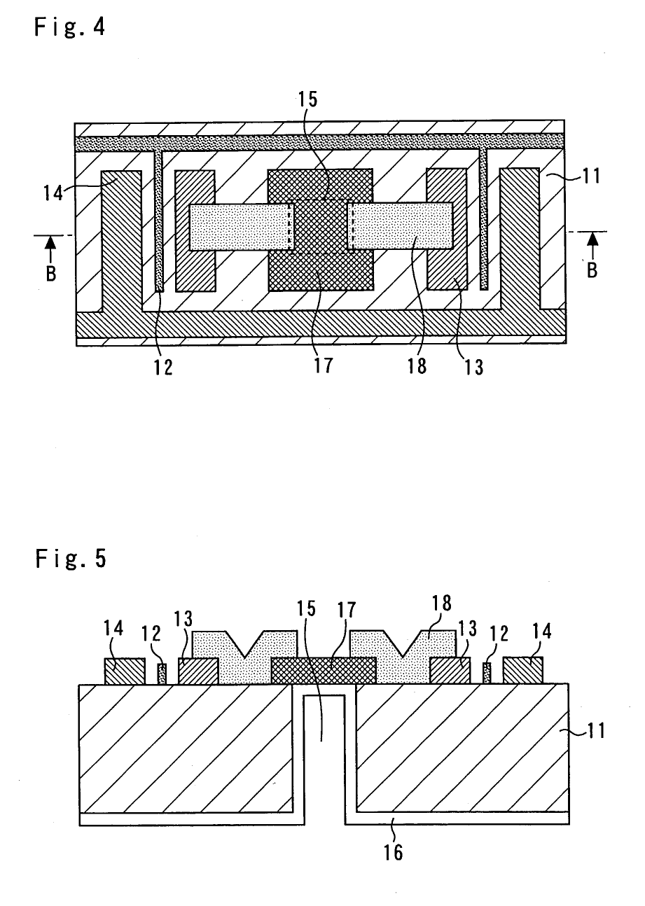

Description will be made below of a method for producing a semiconductor device according to the present invention with reference to FIG. 3.

First of all, the metal layer 8, the gate electrodes 3, and the drain ohmic electrodes 5 are formed on the obverse side of the semiconductor substrate 2, as shown in FIG. 3(a). A GaAs substrate, for example, is used as the semiconductor substrate 2. The metal layer 8 is made up of a conductive material which does not react with the etching liquid or the etching gas at the time of the etching. For example, the metal layer 8 is formed by depositing Ti and Au to form a laminated metal and processing the laminated metal by using of the lift-off method. In this case, the film thicknesses of the lower layer of Ti and the upper layer of Au may be set to 500 Å and 2 μm, respectively. The gate electrodes 3 are formed by depositing, for example, Ti/Au, or Ti/Al to form a laminated metal and processing the laminated metal by using of the lift-off method. The drain ohmic electrodes are formed by depositing, for example, Au/Ge/Ni/Au to form a laminated metal and processing the laminated metal by using of the lift-off method. The metal layer 8, the gate electrodes 3, and the drain ohmic electrodes 5 may not be formed in that order. Any one of them may be formed first.

According to the present invention, the metal layer is disposed right over the via hole which is formed after the metal layer. Therefore, it is necessary to set the dimensions of the metal layer such that the via hole is not exposed to the obverse side of the semiconductor substrate due to occurrence of overetching at the time of forming the via hole or misalignment at the time of forming the metal layer. Specifically, the size of the metal layer is determined by adding the alignment margin for the formation of the metal layer to the size of the via hole. For example, the long sides of the metal layer 8 having a rectangular shape may be set to have a length equal to the sum of the length of the long sides of the via hole 6 and the alignment margin, while the short sides of the metal layer 8 may be set to have a length equal to the sum of the length of the short sides of the via hole 6 and the alignment margin, as shown in FIG. 1.

Next, the source ohmic electrode 4 is formed on the metal layer 8, as shown in FIG. 3(b). For example, the source ohmic electrode 4 is formed by depositing Au/Ge/Ni/Au to form a laminated metal and processing the laminated metal by using of the lift-off method. At that time, the source ohmic electrode 4 is formed such that the source ohmic electrode 4 entirely covers the metal layer 8 and edges of the source ohmic electrode 4 are in ohmic contact with the semiconductor substrate 2. Therefore, the dimensions of the source ohmic electrode 4 are determined by taking into account the dimensions of the metal layer 8, the contact length (indicated by W₄ in FIG. 2) between the source ohmic electrode 4 and the semiconductor substrate 2, and the alignment margin for the formation of the source ohmic electrode 4. For example, the long sides of the source ohmic electrode 4 having a rectangular shape may be set to have a length equal to the sum of the length of the long sides of the metal layer 8, the contact length, and the alignment margin, while the short sides of the source ohmic electrode 4 may be set to have a length equal to the length of the short sides of the metal layer 8, the contact length, and the alignment margin, as shown in FIG. 1.

Then, as shown in FIG. 3(c), a mask layer 10 is formed on the reverse side of the semiconductor substrate 2. The mask layer 10 is made up of a resist film, etc. and has an opening portion 9 at a position corresponding to that of the metal layer 8. Then, as shown in FIG. 3(d), the semiconductor substrate 2 is etched by using of a wet etching method or an anisotropic dry etching method to form the via hole 6. According to the present invention, the position on the semiconductor substrate 2 at which the via hole 6 is formed corresponds to that at which the source ohmic electrode 4 is formed. However, since the metal layer 8 is disposed between the via hole 6 and the source ohmic electrode 4 and acts as an etching stopper, the source ohmic electrode 4 does not come into direct contact with the etching liquid or the etching gas at the time of the etching. Therefore, it is possible to form the via hole 6 under the source ohmic electrode 4 without damaging the source ohmic electrode 4.

Lastly, the inside surface of the via hole 6 and the entire reverse side of the semiconductor substrate 2 are plated with Au to form the ground electrode 7, as shown in FIG. 3(e).

According to the present invention described above, on a semiconductor substrate, a source ohmic electrode is formed over a via hole, making it possible to miniaturize the semiconductor device. Furthermore, since a metal layer is disposed between the source ohmic electrode and the via hole and used as an etching stopper for the formation of the via hole, it is possible to form the via hole without damaging the source ohmic electrode at the time of the etching.

The present embodiment described above is applied to when a source ohmic electrode is formed over a metal layer. However, the present invention is not limited to this specific case. For example, the present invention may be applied to a structure in which a drain ohmic electrode is formed over a metal layer, depending on the circuit configuration of the device.

The features and advantages of the present invention may be summarized as follows.

According to one aspect, a via hole is formed under an electrode. Therefore, it is possible to obtain a miniaturized semiconductor device.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-214777, filed on Jul. 24, 2002 including specification, claims, drawings and summary, on which the Convention priority of the present application is based, are incorporated herein by reference in its entirety.

What is claimed is:

1. A semiconductor device comprising:
a semiconductor substrate;
a metal layer formed on a surface of said semiconductor substrate;
an electrode formed such that said electrode covers said metal layer, edges of said electrode being in ohmic contact with said semiconductor substrate;
a via hole formed right under said metal layer, said via hole having a depth reaching said metal layer from a reverse side of said semiconductor substrate; and
a ground electrode formed on an inside surface of said via hole and said reverse side of said semiconductor substrate, said ground electrode being connected to said electrode through said metal layer.

2. The semiconductor device according to claim 1, wherein said metal layer and said electrode each has a rectangular shape.

3. The semiconductor device according to claim 1, wherein said electrode is a source electrode of a field effect transistor.

4. The semiconductor device according to claim 1, wherein said metal layer has a laminated structure made up of a lower layer of titanium and an upper layer of gold.
